(19) United States
(12) Patent Application Publication
(10) Pub. No.: US 2011/0031982 A1
(43) Pub. Date: Feb. 10, 2011

(54) Tamper-resistant electronic circuit and module incorporating electrically conductive nano-structures

(75) Inventors: John Leon, Anaheim Hills, CA (US); James Yamaguchi, Laguna Niguel, CA (US); Volkan Ozguz, Aliso Viejo, CA (US); W. Eric Boyd, Irvine, CA (US)

Correspondence Address: W. ERIC BOYD, ESQ.;IRVINE SENSORS CORP., 3001 REDHILL AVENUE, BUILDING 4, SUITE 108, COSTA MESA, CA, 92626, US

(73) Assignee: Irvine Sensors Corporation, Costa Mesa, CA (US)

(21) Appl. No.: 12/806,127

(22) Filed: Aug. 4, 2010

Related U.S. Application Data
(60) Provisional application No. 61/273,573, filed on Aug. 6, 2009.

(51) Int. Cl. G01R 27/28; H02H 3/08; H05K 7/00

(52) U.S. Cl. 324/649; 361/93.1; 361/783

(57) ABSTRACT

A device and method are disclosed comprising one or more electrically conductive nano-structures defined on one or more surfaces of a microelectronic circuit such as an integrated circuit die, microelectronic circuit package (such as a TSOP, BGA or other prepackaged IC) a stacked microelectronic circuit package, or on the surface of one or more layers in a stack of layers containing one or more ICs.

In one embodiment, the electrically conductive nano-structure is in electrical connection with a monitoring circuit and acts as a “trip wire” to detect unauthorized tampering with the device or module. Such a monitoring circuit may include a power source such as an in-circuit or in-module battery and a “zeroization” circuit within the chip or package to erase the contents of a memory when the electrically conductive nano-structure is breached or altered. The device may be configured to blow one or more fuses or overcurrent protection devices when the electrically conductive nano-structure is breached or altered.

In a further embodiment, one or more electrically conductive nano-structures are used to interconnect and reroute one or more electrical connections between one or more ICs (or dummy leads and vias) to create an “invisible” set of electrical connections on the chip or stack to obfuscate an attempt to reverse engineer the device, i.e., a set of connections that cannot be observed by standard test means such as by X-ray or conventional microscope.

### CROSS-REFERENCE TO RELATED APPLICATIONS

This application claims the benefit of U.S. Provisional Patent Application No. 61/273,573, filed on Aug. 6, 2010 entitled “Anti Tamper Device with Zeroization Nano Structure” pursuant to 35 USC 119, which application is incorporated fully herein by reference.

### STATEMENT REGARDING FEDERALLY SPONSORED RESEARCH AND DEVELOPMENT

N/A

### DESCRIPTION

1. Field of the Invention

The invention relates generally to the field of electronic packages comprising one or more tamper-resistant features. More specifically, the invention relates to the use of electrically conductive nano-structures for the monitoring and protection of an electronic circuit.

2. Background of the Invention

It is a known concern of military and commercial entities that reverse engineering and evaluation of an electronic circuit can occur when such an electronic device (e.g., a microelectronic circuit) falls in to enemy hands or into the possession of a business competitor. The U.S. government has expressly noted such a concern in a recent directive entitled, “DoD Directive 5200.39, “Research and Technology Protection within the Department of Defense,” issued in March 2002.

Military opponents or commercial competitors can gain an advantage by learning the operation and vulnerability of a circuit by electronic probing or by physically examining the circuit such as by X-ray or by mechanically or chemically removing circuit or package structures to understand and view the circuit in order to duplicate or develop methods of defeating the circuit.

In view of the above, making the reverse engineering of a protected circuit difficult or impossible without complex test equipment is needed. Such protection is needed to minimize the possibility an adversary learns key features and functions of a protected circuit and develops means to disable or imitate the device.

### SUMMARY OF THE INVENTION

The device and method of the invention comprises the use of one or more electrically conductive nano-structures defined on one or more surfaces of a microelectronic circuit such as an integrated circuit die, microelectronic circuit package (such as a TSOP, BGA or other prepackaged IC formats), a stacked microelectronic circuit package or on the surface of one or more layers in a stack of layers containing one or more ICs.

In one embodiment, the electrically conductive nano-structure acts as a sensor for detection of a predetermined variance in a predetermined electrical characteristic of the electrically conductive nano-structure. The electrically conductive nano-structure is in electrical connection with a monitoring circuit and together the elements act as an electronic “trip wire” to detect unauthorized tampering with the device or module. Such a monitoring circuit may include an internal or external power source (e.g., an in-circuit or in/module battery) in combination with a related “zeroization” circuit within the chip or package to erase the contents of a memory when the electrically conductive nano-structure is breached. In an alternative embodiment, the device may be configured to blow one or more fuses, fusible links or current overprotection devices when the electrically conductive nano-structure is breached.

In a further embodiment, one or more electrically conductive nano-structures are used to interconnect and reroute one or more electrical connections between one or more ICs (or act as dummy leads, connections and/or conductive through-hole vias) to create an “invisible” set of electrical connections on or in the chip or stack, i.e., a set of electrical connections that cannot be easily observed by standard test or reverse engineering means such as by X-ray or conventional microscope.

In a first aspect of the invention, a tamper-resistant device and module are provided comprising an electronic monitoring circuit, an electrically conductive nano-structure having a predetermined electrical characteristic in electrical connection with the electronic monitoring circuit and wherein the electronic monitoring circuit is configured whereby a predetermined variance in the predetermined electrical characteristic initiates a predetermined response from the monitoring circuit.

In a second aspect of the invention, a tamper-resistant device and module are provided comprising a stack of layers wherein at least two of the layers each comprise one integrated circuit chip in electrical connection with at least one electrically conductive nano-structure.

These and other aspects of the invention are disclosed in the detailed description that follows below.

### BRIEF DESCRIPTION OF THE DRAWINGS

FIG. 1 depicts a cross-section of a stack comprised of two layers depicting an exemplar conductive through-hole via and an exemplar T-connect structure.

FIG. 2 depicts a stack showing exemplar embodiments of various electrically conductive nano-structures on the surface of the stack and on the major surface of a layer in the stack.

FIG. 3 shows an exemplar embodiment of an electrically conductive nano-structure for use with a monitoring circuit to detect a change in capacitance.

FIG. 4 shows an exemplar embodiment of an electrically conductive nano-structure for use with a monitoring circuit in a vertical orientation to detect a change in resistance.

FIG. 5 shows an exemplar embodiment of an electrically conductive nano-structure for use with a monitoring circuit in a horizontal orientation to detect a change in resistance.

FIGS. 6 and 7 illustrate alternative preferred embodiments of a tapered electrically conductive trace.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Stacked microelectronic modules comprised of layers containing integrated circuitry are desirable in that the three-dimensional structure provides increased circuit density per unit area. The elements in a module are generally arranged in a stacked configuration and may comprise stacked silicon die, stacked prepackaged integrated circuit packages, stacked modified prepackaged integrated circuit or stacked neo-layers such as are disclosed in the various U.S. patents below.

The patents below disclose inventions wherein layers containing integrated circuits chips are stacked and interconnected using any of a number of stacking techniques known to those skilled in the art. For example, Irvine Sensors Corporation, assignee of the instant application, has developed several patented techniques for stacking and interconnecting multiple integrated circuits. Some of these techniques are disclosed in U.S. Pat. Nos. 4,525,921; 4,551,629; 4,646,128; 4,706,166; 5,104,820; 5,347,428; 5,432,729; 5,688,721; 5,953,588; 6,117,704; 6,560,109; 6,706,971; 6,717,061; 6,734,370; 6,806,559 and U.S. Pub. No. 2006/0087883.

Generally speaking, components containing integrated circuits are bonded together one on top of another so as to maintain a footprint equivalent to that of the largest layer in the stack. The input/output connections of the integrated circuit die in the layers are routed to the edges of the components or to area interconnects or electrically conductive vias defined in one or more of the layers.

T-connect structures for interconnecting one or more layers can be defined by electrically routing the input/output connections of the ICs in the layers to the edges of the layers whereby the input/output connections are electrically accessible on the sides of the component stack. These input/output connections are then electrically interconnected on the sides of the component stack using photolithographic and conductive plating processes to create T-connects using techniques such as those described in the patents identified above.

Alternatively, electrically conductive vias may be defined at predetermined locations and used to electrically interconnect one or more layers in a stack.

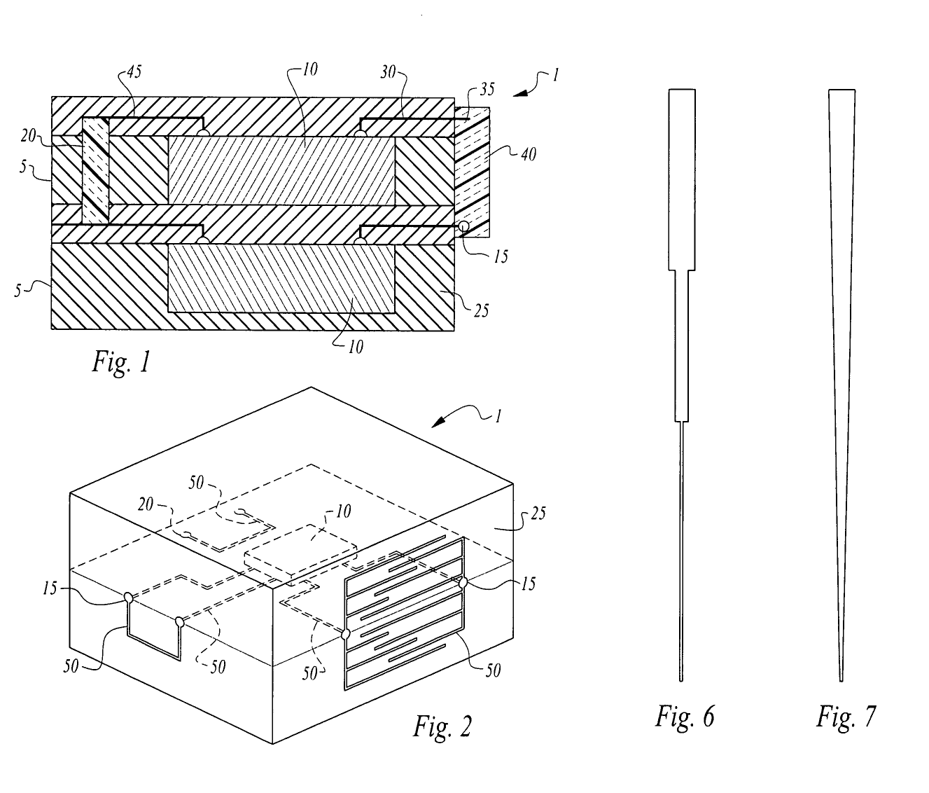

Turning to FIG. 1, the cross-section of an electronic module 1 comprising two layers 5 is shown, each layer comprising a semiconductor integrated circuit chip 10 (ICs). FIG. 1 depicts a T-connect structure 15 and an electrically conductive through-hole via 20 as two examples of layer interconnection methods.

As depicted in FIG. 1, layers 5 are stacked and bonded together. Each layer 5 includes integrated circuit 10 and is encapsulated in potting or encapsulating dielectric material 25. Electrically conductive input/output traces extend to the edges of the stack to define access leads 35.

One technique exemplified in FIG. 1 is the use of a plated conductive side bus to electrically interconnect access leads 35. An electrically conductive side bus 40 in the form of a trace or wire or equivalent structure is defined or disposed on a lateral surface of the stack to interconnect the two layers at the predefined access leads 35.

Another technique exemplified in FIG. 1 is the use of metallization and electrically conductive vias to electrically interconnect the layers. As depicted, conductive traces or wires 45 extend and are interconnected with an electrically conductive through-hole via 20 defined at one or more predetermined locations.

The use of area vias such as via 20 provides significant advantages over the use of a conductive wire or trace formed on a lateral surface of the component stack. For example, the use of vias both hides and protects the interconnections between components within the stack. However, different embodiments of the invention may use either of these techniques by themselves, or a combination of these techniques to interconnect components and layers. In addition, it is noted that FIG. 1 only depicts one interconnection on a side of the stack. One skilled in the art will recognize that the present invention contemplates several such interconnections on one or more sides of the component stack of a tamper-resistant module arranged according to different embodiments of the invention.

The routing and interconnection of input/output connectors within the tamper-resistant module provides a tamper-resistant mechanism by allowing the input/output connectors accessible to an external system to be obfuscated or scrambled. As described above, the input/output connectors of the integrated circuit chips stacked in the tamper-resistant module may be routed to the edges of the stack and then interconnected. This allows the arrangement of the input/output connectors of one component connected to the connection layer to be different than the arrangement of the input/output connectors of the connection layer itself.

In a first embodiment of the invention shown in FIG. 2, one or more electrically conductive nano-structures 50 are defined on one or more surfaces of a microelectronic circuit, package or module surface comprised of a stack of integrated circuit chips. The electrically conductive nano-structures 50 are preferably comprised of at least one plated metallic structure comprising, for instance, titanium, titanium-tungsten, gold, copper or aluminum material.

The width of the electrically conductive nano-structure or trace is preferably less than 200 nm where observation by standard inspection procedures difficult and desirably less than 70 nm where inspection by X-ray methods cannot detect the nano-structures.

The electrically conductive nano-structures are defined on the one or more surfaces by means of nano-imprint lithography, nano-patterning or other nano-means as are known to those skilled in the art of nano-technology structure fabrication.

Because of the very small feature size, electrically conductive nano-structures 50 are not readily discernable to the naked eye, conventional microscope, laser or X-ray analysis or other common means of module or chip analysis. The fine trace widths of electrically conductive nano-structures 50 are generally finer than the resolution of a focused ion beam (FIB) such that unauthorized attempts to modify a circuit using FIB risk the destruction or alteration of a electrically conductive nano-structure which is sensed by a monitoring circuit and initiates a predetermined response, (i.e., blowing of one or more fuses in the circuit, erasure of memory contents or the inoperability of the circuit being examined). This results in a significant increase in the difficulty of an adversary's ability to detect the electrically conductive nano-structure before it is breached, altered or destroyed, particularly in the embodiment where the electrically conductive nano-structure is embedded or encapsulated in an opaque potting compound.

In one embodiment, the electrically conductive nano-structure is in electrical connection with protection or monitoring circuitry in the chip, package or stack of packages such as by a conductive T-connected defined at an access lead. The monitoring circuit may comprise circuitry that detects a predetermined variance of a physical or electrical characteristic in or of the electrically conductive nano-structure such as, but not limited to, a change to an electrical open circuit in the electrically conductive nano-structure, a change to an electrical short circuit in the electrically conductive nano-structure, a change in resistance in the electrically conductive nano-structure, change in capacitance in the electrically conductive nano-structure, a change in impedance in the electrically conductive nano-structure, changes in temperature in the electrically conductive nano-structure, a change in inductance in the electrically conductive nano-structure or change in resonant frequency or timing in the electrically conductive nano-structure (such as when the electrically conductive nano-structure is in the form of an R/C, R/L, R/L/C or similar circuit) when the electrically conductive nano-structure on the surface of the device is altered, modified or broken.

In other words, an electrically conductive nano-structure incorporated with monitoring circuitry can be electrically or functionally characterized under a set of predetermined operating characteristics and, in the event the electrically conductive nano-structure is altered or breached and one or more of the electrical or functional characteristics changes, a predetermined response from a monitor circuit is initiated.

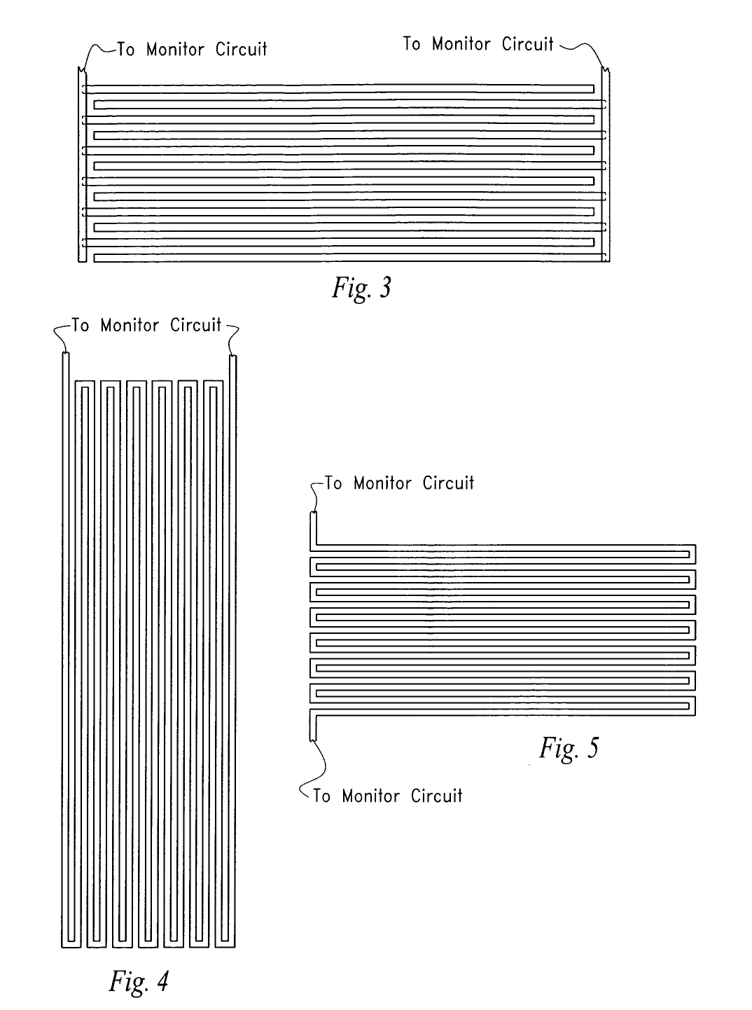

FIG. 3 shows an exemplar embodiment of an electrically conductive nano-structure for use with a monitoring circuit to detect a change in capacitance.

FIG. 4 shows an exemplar embodiment of an electrically conductive nano-structure for use with a monitoring circuit in a vertical orientation to detect a change in resistance.

FIG. 5 shows an exemplar embodiment of an electrically conductive nano-structure for use with a monitoring circuit in a horizontal orientation to detect a change in resistance.

The electrically conductive nano-structure is disposed on the device or module such that when an adversary physically alters the electrically conductive nano-structure on the surface of the device such as by mechanically or chemically altering the module, improperly handling the module, or by subjecting the physically and electrically delicate electrically conductive nano-structure to a physical, chemical or electrical event that generates a change in a predetermined set of electrically conductive nano-structure characteristics.

The alteration and its affect on the characteristics of the electrically conductive nano-structure is sensed by a circuit provided in the device or module and is configured to produce a predetermined response such as the erasing of a memory contents in the module or the reconfiguring of one or more logical circuits within the device to logically reroute one or more predetermined connections between devices in the module as may be incorporated into a field programmable gate array or other programmable logic device.

In an alternative embodiment, a breach or alteration of the electrically conductive nano-structure in connection with a monitoring circuit is configured to result in the blowing one or more integrated circuit fusible links, fuses or overcurrent protection devices as known in the semiconductor fabrication art and as are fabricated from, for instance, aluminum or polysilicon.

In yet a further embodiment, a breach or alteration of the electrically conductive nano-structure can be configured to incorporate a configurable logic device. Specifically, a configurable logic device is used to logically re-route connections between components within the circuit or module when a predetermined variance in an electrical or physical characteristic of the nano-structure is sensed by the monitoring circuit.

Such devices may comprise a field programmable gate array or a field programmable interconnect device that is capable of being configured to form logical circuits connecting different input/output connectors. The logical circuits are created using configuration information such as code in a hardware description language that is loaded into the configurable logic device. This code may be loaded at the time of manufacture or first use to permanently configure the logical circuits, thereby hardwiring the configurable logic device.

Alternatively, the code may be loaded when the device is connected to an external system and is provided power to execute configuration processes. Another alternative is to store the code in memory or in a portion of the configurable logic device configured as memory, and load the code from this location rather than from an external system. The general structure and techniques for programming FPGAs and FPIDs are known to those skilled in the art and will not be discussed further in this description.

In a further alternative embodiment, the I/O signature of a device is defined herein as electrical pattern, voltage level, timing parameter, slew rate, physical location, die-pad, etc. that can be used to identify the type of output signal from an integrated circuit die, stack of die (or any structure). As a non-limiting example, one characteristic, the pattern of data, can be used to identify a signal without knowing anything else, e.g., a clock line is easily identified by a continuous stream of pulses. Another non-limiting example of an I/O of signature are characteristics such electrical voltage levels/rise times, etc., e.g., the presence of a signal and complement can easily identify a differential pair or voltage swings can identify related I/O (e.g. 1.8V I/O or 3.3 VIO).

Timing I/O signatures can play an important role in identifying a device or circuit, e.g., a group of 32 lines that always transition identically can be identified as a data bus. Along this line, an unauthorized tamper attempt could involve loading signals into a device or circuit to determine input or output, drive strength, and logic thresholds. Other possible I/O signatures include identification of die pads, pad locations etc. As a non-limiting example, knowing the type of chip and which side I/O come out can beneficially assist in identifying the nature of the circuitry of the die or stack. Since the electrically conductive nano-structures of the invention routes are completely passive, such structures are used for I/O signature modification such as obfuscating or hiding connections, adding signals, or changing apparent routability of pins.

With the above in mind, a fake or misleading I/O signature can be created by an electrically conductive nano-structure.

In this aspect of the invention, the device comprises one or more “fake die”, or a general purpose component specifically created for electrical I/O obfuscation that is embedded within the stack or in a layer, (referred to an “active obfuscating component” herein).

The fake die takes any inputs available in system and creates outputs based off the inputs, connected by one or more electrically conductive nano-structures using, for instance a scrambling technique (linear feedback shift register for simple case). As a non-limiting example, in a stack consisting of a data and address bus, a few data signals, address signals and a control line are routed using electrically conductive nano-structures to the “fake die” which in turn produces outputs that are routed within the stack and/or to the outside to create additional I/O signatures. These additional signals obfuscate the operation of the tamper-resistant circuit or stack. The electrically conductive nano-structures provide a means of almost invisibly interconnecting and routing inputs and outputs to the fake die within structure due to minimal visibility from x-ray and other inspection methods.

In a more direct approach, electrically conductive nano-structures are used to perform final connection of die pads in a hidden manner. The die are routed such that I/O lines appear to go to an apparent die-pad, but in actuality a hidden electrically conductive nano-structure reroutes the trace from the apparent die pad to different die pad on the chip. In this manner, the main reroute appears visible on one side of the die, but in fact the electrically conductive nano-structures re-routes it elsewhere.

Electrically conductive nano-structures may be provided such that they fuse open upon probing (such as a logic analyzer probe). The fusing is easily be detected by a loopback. To implement in an active structure, the electrically conductive nano-structures are routed out to fake I/O and/or to fake traces/test points to “invite” probing. This technique may alternatively be applied using a sensor chip embedded in structure as well without the use of electrically conductive nano-structures.

In yet a further alternative embodiment, a combination of electrically conductive through-hole vias, T-connect structures and electrically conductive nano-structures in the form of nano-scale conductive traces are defined in a module surface or on the major surface of one or more layers in a stack or on a prefabricated integrated circuit chip or package or modified package to obfuscate the layout and function of the circuitry contained therein by significantly increasing the difficulty in identifying, understanding or viewing the nano-structures owing to their very small feature size.

Further, one or more electrically conductive nano-structures can be defined upon a major surface (as opposed to a side surface) of an IC chip or layer in a stack and interconnected with one or more electrically conductive through-hole vias and/or T-connect structures whereby an attempt to reverse engineer the operation and structure of the circuit or module is significantly inhibited in that conventional X-ray or microscopic inspection is unable to detect or identify the location and connection points of the electrically conductive nano-structures in combination with vias and/or T-connects.

To further inhibit or delay reverse engineering, one or more “blind” or dummy vias, T-connects and/or electrically conductive nano-structures may be provided at one or more predetermined locations. For instance, one of more of the electrically conductive nano-structures, through-hole vias, T-connect structures and/or internal or external conducive traces may be provided as a dummy or blind element, i.e., not in electrical connection with a device or acting as an electrical “open” circuit.

The “labyrinth” created by the combination of viewable conductive traces in combination with the virtually indiscernible electrically conductive nano-traces, dummy and functional T-connects and dummy and functional through-hole vias create an IC chip, prepackaged part or stacked electronic module that is significantly difficult to characterize in both an unpowered and powered state if an adversary attempts to reverse engineer the part.

As discussed above, the instant invention comprises electrically conductive nano-scale traces, generally 1 μm wide or much smaller, which must be electrically interconnected to a next level metallization through, for instance, a conductive through-hole via structure.

This invention improves the integrity of the metal contact between the nano-scale conductive traces and vias by providing for the progressive enlarging of the original 1 μm or smaller width trace using a series of wider and wider steps or by the tapering of the traces. Preferred embodiments of these elements are depicted in FIGS. 6 and 7.

This desirably provides a gradual progression from a small conductive trace interconnection to a wider conductive trace interconnection and minimizes electrically overstressing the micron to sub-micron trace.

The enhanced via/nano-scale conductive trace contact area permits subsequent electrical interconnections. For instance, a contact area within a 100 micron square via to a 25 micron trace is 2500 sq. microns whereas a contact area of a 100 micron square via to a 1 micron trace is only 100 sq. microns.

The fabrication of the preferred tapered nano-scale conductive traces of the invention may comprise the steps of trace structure delineation by photolithography, using any of the known industry standard procedures. Metallization is then accomplished preferably by vacuum deposition or other known procedures using processes known in the art of photolithographic plating such as lift-off and print-and-etch technologies.

Yet further, the IC chip, prepackaged part or stack of layers may be encapsulated in a tamper-respondent enclosure such is available from W. L. Gore & Associates, Inc. and configured to trigger a predetermined circuit response, for instance the blowing or a fuse or the erasure of the contents of an embedded memory device. Examples of such tamper-respondent enclosures include U.S. Pat. Nos. 5,539,379 and 5,858,500 assigned to W.L. Gore & Associates, Inc. and each of which are incorporated herein by reference.

In yet a further embodiment, the instant invention is desirably coated, potted or embedded with an opaque material such as silica filled epoxy or glass bead filled epoxy. Alternatively, coating or embedding the device in a material that inhibits or absorbs X-ray energy provides an additional obfuscation layer in the event attempts to examine the device by X-ray occur.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

We claim:

1. A tamper-resistant device comprising:
an electronic monitoring circuit,
an electrically conductive nano-structure having a predetermined electrical characteristic in electrical connection with the electronic monitoring circuit, and,
the electronic monitoring circuit configured whereby a predetermined variance in the predetermined electrical characteristic initiates a predetermined response from the monitoring circuit.

2. The device of claim 1 wherein the predetermined electrical characteristic comprises a predetermined electrical resistance.

3. The device of claim 1 wherein the predetermined electrical characteristic comprises a predetermined electrical capacitance.

4. The device of claim 1 wherein the predetermined electrical characteristic comprises a predetermined electrical inductance.

5. The device of claim 1 comprising at least on active obfuscating component.

6. The device of claim 1 wherein the predetermined response comprises disabling a circuit element by means of an overcurrent protection device.

7. The device of claim 1 wherein the predetermined response comprises erasing the contents of an electronic memory.

8. The device of claim 1 wherein the predetermined response comprises logically reconfiguring a first connection point in the device to a second connection point in the device.

9. A tamper-resistant module comprising:
a stack of layers wherein at least two of the layers each comprise at least one integrated circuit chip,
wherein at least one of the layers comprises an electronic monitoring circuit and an electrically conductive nano-structure having a predetermined electrical characteristic in electrical connection with the electronic monitoring circuit, and,
the electronic monitoring circuit configured whereby a predetermined variance in the predetermined electrical characteristic initiates a predetermined response from the monitoring circuit.

10. The device of claim 9 wherein the predetermined electrical characteristic comprises a predetermined electrical resistance.

11. The device of claim 9 wherein the predetermined electrical characteristic comprises a predetermined electrical capacitance.

12. The device of claim 9 wherein the predetermined electrical characteristic comprises a predetermined electrical inductance.

13. The device of claim 9 wherein the predetermined electrical characteristic comprises a predetermined electrical impedance.

14. The device of claim 9 wherein the predetermined response comprises disabling a circuit element by means of an overcurrent protection device.

15. The device of claim 9 wherein the predetermined response comprises erasing the contents of an electronic memory.

16. The device of claim 9 wherein the predetermined response comprises logically reconfiguring a first connection point to a second connection point.

17. A tamper-resistant module comprising:
a stack of layers wherein at least two of the layers each comprise at least one integrated circuit chip in electrical connection with at least one electrically conductive nano-structure.

18. The device of claim 17 wherein the electrically conductive nano-structure is in electrical connection with at least one electrically conductive through-hole via.

19. The device of claim 17 wherein the electrically conductive nano-structure is in electrical connection with at least one electrically conductive T-connect structure.

20. The device of claim 17 wherein the electrically conductive nano-structure is tapered and in electrical communication with at least one electrically conductive through-hole via or electrically conductive T-connect structure.
